(19) United States
(12) Patent Application Publication
(10) Pub. No.: US 2023/0297331 A1
(43) Pub. Date: Sep. 21, 2023

(54) SYSTEM AND METHOD FOR FAST AND EFFICIENT MAX/MIN SEARCHING IN DRAM

(71) Applicants: Deliang Fan, Tempe, AZ (US); Fan Zhang, Tempe, AZ (US); Shaahin Angizi, Newark, NJ (US)

(72) Inventors: Deliang Fan, Tempe, AZ (US); Fan Zhang, Tempe, AZ (US); Shaahin Angizi, Newark, NJ (US)

(73) Assignee: Arizona Board of Regents on behalf of Arizona State University, Scottsdale, AZ (US)

(21) Appl. No.: 18/187,189

(22) Filed: Mar. 21, 2023

Related U.S. Application Data
(60) Provisional application No. 63/321,937, filed on Mar. 21, 2022.

(51) Int. Cl. G06F 7/02; G06F 7/78; H03K 19/21

(52) U.S. Cl. CPC G06F 7/02; G06F 7/78; H03K 19/21

(57) ABSTRACT

A method of calculating a boundary value of a set of numerical values in a volatile memory comprises storing a set of numerical values in a volatile memory, initializing a comparison vector, initializing a matching vector, transpose-copying a first bit of each of the set of numerical values into a buffer, calculating a result vector, updating the matching vector, repeating the previous steps for each of the bits in the set of numerical values, and returning the matching vector, where the position of each 1 remaining in the matching vector corresponds to an index of the boundary value in the set of numerical values, wherein the computation and the memory storage take place on the same integrated circuit. A system for calculating a boundary value of a set of numerical values is also disclosed.

### CROSS-REFERENCE TO RELATED APPLICATIONS

This application claims priority to U.S. Provisional Application No. 63/321,937, filed on Mar. 21, 2022, incorporated herein by reference in its entirety.

### STATEMENT REGARDING FEDERALLY SPONSORED RESEARCH OR DEVELOPMENT

This invention was made with government support under 2005209 and 2003749 awarded by the National Science Foundation. The government has certain rights in the invention.

### BACKGROUND OF THE INVENTION

In the era of big data, min/max searching from bulk data arrays is one of the most important and widely used fundamental operations in data-intensive applications such as sorting, ranking, bioinformatics, data mining, graph processing and route planning (R. V. Lebo, 1982, Cytometry: The Journal of the International Society for Analytical Cytology, vol. 3, pp. 145-154; M. A. Ismail et al., 1989, Pattern recognition, vol. 22, pp. 75-89; L. Page et al., 1999, Stanford InfoLab, Tech. Rep.). Online news and social media require real-time ranking using fast min/max searching from massive data stores to evaluate trending information to display on their sites. The process of min/max searching is the most time-consuming computation in many large-scale graph processing algorithms addressing famous optimization issues such as the travelling salesmen problem.

However, implementing fast and efficient min/max searching for big data faces significant challenges in conventional computer systems with respect to memory architecture and computing algorithms. Within memory architectures, the well-known ‘memory-wall’ challenge causes significant issues, like long off-chip memory access latency, data congestion due to limited memory bandwidth and two-orders higher energy consumption in data movement than data processing (A. Boroumand et al., 2018, SIGPLAN Not., vol. 53, no. 2, p. 316-331). Within computing algorithms, min/max searching is in general a comparison-based algorithm, where the CPU needs to compare every element serially for colossal amounts of raw data. Such computing properties cause min/max searching to demand ultra-high computing resources and power.

The above challenges naturally motivate researchers to explore implementing fast and efficient min/max searching operations within memory where bulk data is stored, to greatly minimize power-hungry and low speed massive off-chip data communication, aligning with the emerging ‘processing-in memory’ (PIM) concept. Among various types of PIM platforms, the ‘in-DRAM computing’ platform is a natural choice for this problem due to its large memory capacity to store bulk data and reduction of off-chip data transfer (V. Seshadri et al., 2017, MICRO, 2017, pp. 273-287; R. V. Lebo, 1982, Pattern recognition, vol 3, pp. 145-154; S. Angizi et al., 2019, IEEE/ACM International Conference on Computer-Aided Design(ICCAD); Q. Deng et al., 2018, DAC, 2018 Issue, pp. 1-6). However, if directly deploying min/max searching in the most popular existing in-DRAM computing platforms, e.g. Ambit (V. Seshadri et al., 2017, MICRO, 2017, pp. 273-287) or DRISA (R. V. Lebo, 1982, Pattern recognition, vol 3, pp. 145-154), it faces two challenges with respect to computing and logical limitations.

Firstly, general-purpose CPUs/GPUs allow for complex computing instructions, whereas in-DRAM computing platforms only support bulk bit-wise Boolean logic and limited instructions. This restriction demands novel designs for ‘min/max-in memory’ algorithms to provide full system compatibility and leverage the benefits of in-DRAM hardware supported operations.

Second, from a logic computing perspective, the min/max searching function naturally relies on X(N)OR-based comparison operations. Existing in-DRAM computing platforms can provide such functionality, however in-memory-logic designs are largely dependent on charge sharing-based majority gates, which require multiple cycles to implement X(N)OR logic (V. Seshadri et al., 2017, MICRO, 2017, pp. 273-287; R. V. Lebo, 1982, Pattern recognition, vol 3, pp. 145-154). For example, Ambit (V. Seshadri et al., 2017, MICRO, 2017, pp. 273-287) requires seven cycles to realize X(N)OR logic. This process requires large power and time allotments due to sizable intermediate data writeback, further reducing the benefits of in-memory computing.

Innovation is required to support complete bulk bit-wise Boolean logic operations optimized for min/max searching in memory based applications. Thus, there is a need in the art for efficient min/max searching algorithms and supporting hardware for bulk data storage that greatly minimizes the time and cost associated with the computing.

### SUMMARY OF THE INVENTION

In one aspect, a method of calculating a boundary value selected from a minimum or a maximum value of a set of N numerical values in a volatile memory comprises storing a set of N numerical values, each being represented by at least K bits, in a volatile memory, initializing a comparison vector of at least N bits with all 1s or all 0s, initializing a matching vector of N bits with all 1s, transpose-copying a first bit of each of the set of N numerical values into an N-bit buffer, calculating a bitwise XNOR of the comparison vector with the N-bit buffer to obtain an N-bit result vector, determining whether the N-bit result vector contains all zeros, if the N-bit result vector does not contain all zeroes, updating the matching vector to set a 0 at each bit position corresponding to a 0 in the N-bit result vector, repeating the previous steps K times for each of the K bits in the set of N numerical values; and returning the matching vector, where the position of each 1 remaining in the matching vector corresponds to an index of the boundary value in the set of N numerical values, wherein the computation and the memory storage take place on the same integrated circuit.

In one embodiment, the boundary value is a minimum and the comparison vector is initialized with all 0s. In one embodiment, the boundary value is a maximum and the comparison vector is initialized with all 1s. In one embodiment, the bitwise XNOR is performed in a single clock cycle. In one embodiment, the step of initializing the comparison vector includes initializing two first comparison vectors of all 1s and initializing two second comparison vectors of all 0s. In one embodiment, the method further comprises refreshing one of the two first comparison vectors while the other of the two first comparison vectors is being used to calculate the result vector, or refreshing one of the two second comparison vectors while the other of the two second comparison vectors is being used to calculate the result vector.

In one embodiment, the method further comprises storing the result vector in an N-bit latch. In one embodiment, the method further comprises disabling the latch if the N-bit result vector contains all zeros.

In one aspect, a system for in-memory boundary value calculation comprises a volatile computer-readable memory storing a set of binary values, a computational array communicatively connected to the volatile computer-readable memory, comprising a buffer, a transposing circuit configured to read data from the volatile computer-readable memory and store a transposed copy of the data into a buffer of the computational array, and a set of combinatorial logic gates configured to return a bitwise result vector from two input vectors stored in the buffer, and a processor configured to calculate a matching vector by iteratively removing any bit positions flagged by the result vector from the matching vector as the combinatorial logic gates iterate along the binary values in the set from a most significant bit to a least significant bit.

In one embodiment, the system further comprises an all-zero detection unit configured to detect when the result vector contains all zeros. In one embodiment, the computational array is configured to not update the matching vector when the all-zero detection unit detects the result vector containing all zeros. In one embodiment, the computational array further comprises at least one vector of constant values stored in the buffer whose value stays constant during the matching vector calculations. In one embodiment, the computational array further comprises a priority encoder configured to update the matching vector with each iteration of the combinatorial logic gates. In one embodiment, the set of combinatorial logic gates comprises first and second inverters configured with different threshold voltages. In one embodiment, the combinatorial logic gates are configured to perform a bitwise XNOR operation on the two input vectors. In one embodiment, the computational array and the volatile computer-readable memory are positioned on a single printed circuit board.

In one embodiment, the processor is positioned on the single printed circuit board. In one embodiment, the computational array and the volatile computer-readable memory are positioned in a single integrated circuit. In one embodiment, the processor is positioned in the single integrated circuit. In one embodiment, the processor is further configured to detect whether the set of binary values are signed, and to change the behavior of the combinatorial logic for a most significant bit of the signed binary values.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1 is a diagram of a computing device.

FIG. 2 shows the pseudo code of the proposed parallel bit-wise min/max in-memory algorithm.

FIG. 3 depicts the parallel bit-wise operations to find the minimum value of an unsigned integer array.

FIG. 4 depicts the parallel bit-wise operations to find the minimum value from a signed fixed point number array.

FIG. 5A and FIG. 5B depict the architecture diagram of the proposed hardware design with the DRAM Chip with multiple banks that share I/O and buffers, the computational sub-array with required components, and the disclosed dual-row activation based XNOR logic and peripheral circuits for other operations.

FIG. 6 Depicts the single-cycle transpose copy operation including the storage and computational array.

FIG. 7 depicts the area overhead (μm²) for a single computational array and a graph of power and cycle comparison for XNOR logic.

FIG. 8 summarizes the distribution and comparison of latency and energy for Min/Max searching within one computational sub-array.

FIG. 9 is a diagram of execution time and energy consumption for various architectures.

### DETAILED DESCRIPTION

The present invention provides a fast and efficient means for searching min/max values within bulk data. The system and method include an algorithm utilizing XNOR conditional statements with parallel bit-wise comparison. The present invention also includes a hardware that hosts and computes the data via in-DRAM computing. The method and system support parallel in-memory searching for minimum and maximum values of bulk data stored in DRAM as unsigned & signed integers, fixed-point and floating-point numbers.

Differentiating from prior works, the disclosed system is optimized with a one-cycle fast XNOR logic in-DRAM operation and in-memory data transpose, which are used to accelerate the proposed Min/Max-in memory algorithm. Example experiments utilizing Max-PIM in big data sorting and graph processing applications show that it could speed up ˜50× and ˜1000× when compared to GPU and CPU, while only consuming 10% and 1% of the energy, respectively. Moreover, comparing with recent representative in-DRAM computing platforms, i.e., Ambit and DRISA, the Max-PIM design could increase speed of computations by ˜3×-10×.

### Definitions

It is to be understood that the figures and descriptions of the present invention have been simplified to illustrate elements that are relevant for a clear understanding of the present invention, while eliminating, for the purpose of clarity, many other elements found in related systems and methods. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of 20%, ±10%, ±5%, +1%, and +0.1% from the specified value, as such variations are appropriate.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, 6 and any whole and partial increments therebetween. This applies regardless of the breadth of the range.

In some aspects of the present invention, software executing the instructions provided herein may be stored on a non-transitory computer-readable medium, wherein the software performs some or all of the steps of the present invention when executed on a processor.

Aspects of the invention relate to algorithms executed in computer software. Though certain embodiments may be described as written in particular programming languages, or executed on particular operating systems or computing platforms, it is understood that the system and method of the present invention is not limited to any particular computing language, platform, or combination thereof. Software executing the algorithms described herein may be written in any programming language known in the art, compiled or interpreted, including but not limited to C, C++, C#, Objective-C, Java, JavaScript, MATLAB, Python, PHP, Perl, Ruby, or Visual Basic. It is further understood that elements of the present invention may be executed on any acceptable computing platform, including but not limited to a server, a cloud instance, a workstation, a thin client, a mobile device, an embedded microcontroller, a television, or any other suitable computing device known in the art.

Parts of this invention are described as software running on a computing device. Though software described herein may be disclosed as operating on one particular computing device (e.g. a dedicated server or a workstation), it is understood in the art that software is intrinsically portable and that most software running on a dedicated server may also be run, for the purposes of the present invention, on any of a wide range of devices including desktop or mobile devices, laptops, tablets, smartphones, watches, wearable electronics or other wireless digital/cellular phones, televisions, cloud instances, embedded microcontrollers, thin client devices, or any other suitable computing device known in the art.

Similarly, parts of this invention are described as communicating over a variety of wireless or wired computer networks. For the purposes of this invention, the words “network”, “networked”, and “networking” are understood to encompass wired Ethernet, fiber optic connections, wireless connections including any of the various 802.11 standards, cellular WAN infrastructures such as 3G, 4G/LTE, or 5G networks, Bluetooth®, Bluetooth® Low Energy (BLE) or Zigbee® communication links, or any other method by which one electronic device is capable of communicating with another. In some embodiments, elements of the networked portion of the invention may be implemented over a Virtual Private Network (VPN).

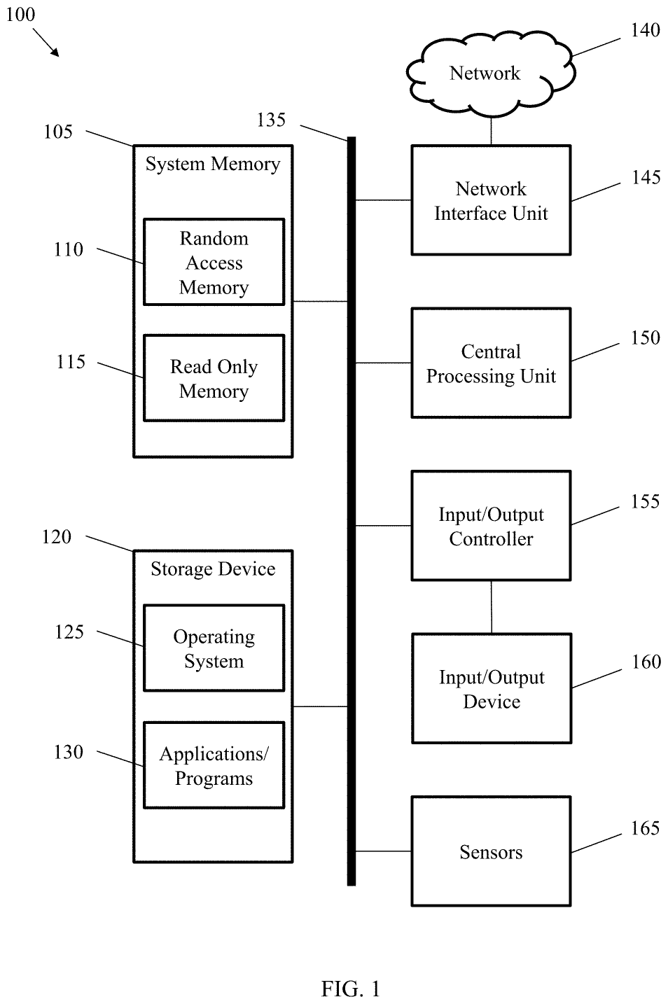

FIG. 1 and the following discussion are intended to provide a brief, general description of a suitable computing environment in which the invention may be implemented. While the invention is described above in the general context of program modules that execute in conjunction with an application program that runs on an operating system on a computer, those skilled in the art will recognize that the invention may also be implemented in combination with other program modules.

Generally, program modules include routines, programs, components, data structures, and other types of structures that perform particular tasks or implement particular abstract data types. Moreover, those skilled in the art will appreciate that the invention may be practiced with other computer system configurations, including hand-held devices, multiprocessor systems, microprocessor-based or programmable consumer electronics, minicomputers, mainframe computers, and the like. The invention may also be practiced in distributed computing environments where tasks are performed by remote processing devices that are linked through a communications network. In a distributed computing environment, program modules may be located in both local and remote memory storage devices.

FIG. 1 depicts an illustrative computer architecture for a computer 100 for practicing the various embodiments of the invention. The computer architecture shown in FIG. 1 illustrates a conventional personal computer, including a central processing unit 150 (“CPU”), a system memory 105, including a random access memory 110 (“RAM”) and a read-only memory (“ROM”) 115, and a system bus 135 that couples the system memory 105 to the CPU 150. A basic input/output system containing the basic routines that help to transfer information between elements within the computer, such as during startup, is stored in the ROM 115. The computer 100 further includes a storage device 120 for storing an operating system 125, application/program 130, and data.

The storage device 120 is connected to the CPU 150 through a storage controller (not shown) connected to the bus 135. The storage device 120 and its associated computer-readable media provide non-volatile storage for the computer 100. Although the description of computer-readable media contained herein refers to a storage device, such as a hard disk or CD-ROM drive, it should be appreciated by those skilled in the art that computer-readable media can be any available media that can be accessed by the computer 100.

By way of example, and not to be limiting, computer-readable media may comprise computer storage media. Computer storage media includes volatile and non-volatile, removable and non-removable media implemented in any method or technology for storage of information such as computer-readable instructions, data structures, program modules or other data. Computer storage media includes, but is not limited to, RAM, ROM, EPROM, EEPROM, flash memory or other solid state memory technology, CD-ROM, DVD, or other optical storage, magnetic cassettes, magnetic tape, magnetic disk storage or other magnetic storage devices, or any other medium which can be used to store the desired information and which can be accessed by the computer.

According to various embodiments of the invention, the computer 100 may operate in a networked environment using logical connections to remote computers through a network 140, such as TCP/IP network such as the Internet or an intranet. The computer 100 may connect to the network 140 through a network interface unit 145 connected to the bus 135. It should be appreciated that the network interface unit 145 may also be utilized to connect to other types of networks and remote computer systems.

The computer 100 may also include an input/output controller 155 for receiving and processing input from a number of input/output devices 160, including a keyboard, a mouse, a touchscreen, a camera, a microphone, a controller, a joystick, or other type of input device. Similarly, the input/output controller 155 may provide output to a display screen, a printer, a speaker, or other type of output device. The computer 100 can connect to the input/output device 160 via a wired connection including, but not limited to, fiber optic, Ethernet, or copper wire or wireless means including, but not limited to, Wi-Fi, Bluetooth, Near-Field Communication (NFC), infrared, or other suitable wired or wireless connections.

As mentioned briefly above, a number of program modules and data files may be stored in the storage device 120 and/or RAM 110 of the computer 100, including an operating system 125 suitable for controlling the operation of a networked computer. The storage device 120 and RAM 110 may also store one or more applications/programs 130. In particular, the storage device 120 and RAM 110 may store an application/program 130 for providing a variety of functionalities to a user. For instance, the application/program 130 may comprise many types of programs such as a word processing application, a spreadsheet application, a desktop publishing application, a database application, a gaming application, internet browsing application, electronic mail application, messaging application, and the like. According to an embodiment of the present invention, the application/program 130 comprises a multiple functionality software application for providing word processing functionality, slide presentation functionality, spreadsheet functionality, database functionality and the like.

The computer 100 in some embodiments can include a variety of sensors 165 for monitoring the environment surrounding and the environment internal to the computer 100. These sensors 165 can include a Global Positioning System (GPS) sensor, a photosensitive sensor, a gyroscope, a magnetometer, thermometer, a proximity sensor, an accelerometer, a microphone, biometric sensor, barometer, humidity sensor, radiation sensor, or any other suitable sensor.

Certain embodiments may include In-DRAM Computing which is defined herein as computation or computing that takes advantage of extreme data parallelism in Dynamic Random Access Memory (DRAM). In some embodiments, a processing unit performing In-DRAM computing as contemplated herein may be located in the same integrated circuit (IC) as a DRAM IC, or may in other embodiments be located in a different integrated circuit, but on the same daughterboard or dual in-line memory module (DIMM) as one or more DRAM IC, and may thus have more efficient access to data stored in one or more DRAM ICs on the DIMM. It is understood that although certain embodiments of systems disclosed herein may be presented as examples in specific implementations, for example using specific DRAM ICs or architectures, these examples are not meant to be limiting, and the systems and methods disclosed herein may be adapted to other DRAM architectures, including but not limited to Embedded DRAM (eDRAM), High Bandwidth Memory (HBM), or dual-ported video RAM. The systems and methods may also be implemented in non-volatile memory based crossbar structures, including but not limited to Resistive Random-Access Memory (ReRAM), Memristor, Magnetoresistive Random-Access Memory (MRAM), Phase-Change Memory (PCM), Ferroelectric RAM (FeRAM) or Flash memory.

The system may also include in-memory computation (IMC) (or in-memory computing) which is the technique of running computer calculations entirely in computer memory (e.g., in RAM). In some embodiments, in-memory computation is implemented by modifying the memory peripheral circuitry, for example by leveraging a charge sharing or charge/current/resistance accumulation scheme by one or more of the following methods: modifying the sense amplifier and/or decoder, replacing the sense amplifier with an analog-to-digital converter (ADC), adding logic gates after the sense amplifier, or using a different DRAM cell design. In some embodiments, additional instructions are available for special-purpose IMC ICs.

The system may also include processing in memory (PIM, sometimes called processor in memory) which is the integration of a processor with RAM (random access memory) on a single IC. The result is sometimes known as a PIM chip or PIM IC.

The present disclosure includes apparatuses and methods for logic/memory devices. In one example embodiment, execution of logical operations is performed on one or more memory components and a logical component of a logic/memory device.

An example apparatus comprises a plurality of memory components adjacent to and coupled to one another. A logic component may in some embodiments be coupled to the plurality of memory components. At least one memory component comprises a partitioned portion having an array of memory cells and sensing circuitry coupled to the array. The sensing circuitry may include a sense amplifier and a compute component configured to perform operations. Peripheral circuitry may be coupled to the array and sensing circuitry to control operations for the sensing circuitry. The logic component may in some embodiments comprise control logic coupled to the peripheral circuitry. The control logic may be configured to execute instructions to perform operations with the sensing circuitry.

The logic component may comprise logic that is partitioned among a number of separate logic/memory devices (also referred to as “partitioned logic”) and which may be coupled to peripheral circuitry for a given logic/memory device. The partitioned logic on a logic component may include control logic that is configured to execute instructions configured for example to cause operations to be performed on one or more memory components. At least one memory component may include a portion having sensing circuitry associated with an array of memory cells. The array may be a dynamic random access memory (DRAM) array and the operations can include any logical operators in any combination, including but not limited to AND, OR, NOR, NOT, NAND, XOR and/or XNOR boolean operations.

In some embodiments, a logic/memory device allows input/output (I/O) channel and processing in memory (PIM) control over a bank or set of banks allowing logic to be partitioned to perform logical operations between a memory (e.g., dynamic random access memory (DRAM)) component and a logic component.

Through silicon vias (TSVs) may allow for additional signaling between a logic layer and a DRAM layer. Through silicon vias (TSVs) as the term is used herein is intended to include vias which are formed entirely through or partially through silicon and/or other single, composite and/or doped substrate materials other than silicon. Embodiments are not so limited. With enhanced signaling, a PIM operation may be partitioned between components, which may further facilitate integration with a logic component's processing resources, e.g., an embedded reduced instruction set computer (RISC) type processing resource and/or memory controller in a logic component.

In the following detailed description of the present disclosure, reference is made to the accompanying drawings that form a part hereof, and in which is shown by way of illustration how one or more embodiments of the disclosure may be practiced. These embodiments are described in sufficient detail to enable those of ordinary skill in the art to practice the embodiments of this disclosure, and it is to be understood that other embodiments may be utilized and that process, electrical, and/or structural changes may be made without departing from the scope of the present disclosure.

### Min/Max-In-Memory Searching Algorithm

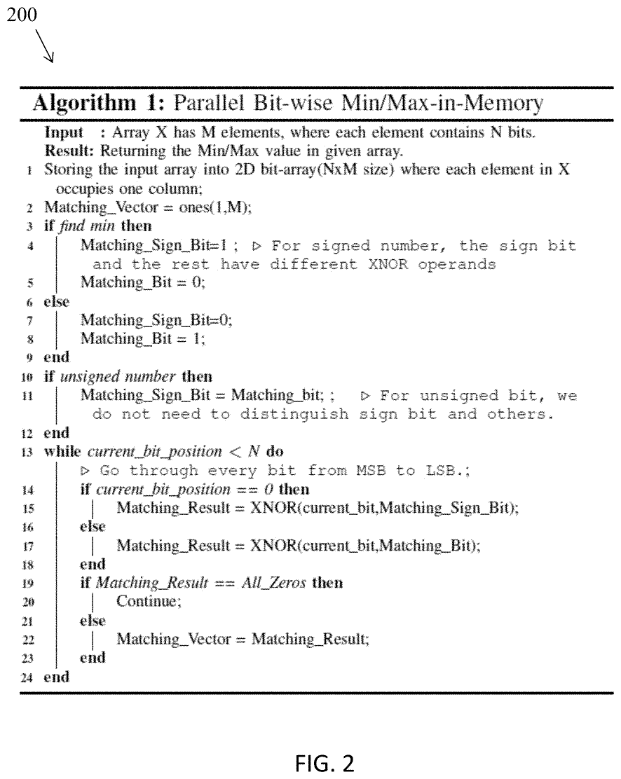

Referring now to FIG. 2, pseudo-code of a novel Min/Max-in-memory searching algorithm based on iterative XNOR bit-wise parallel comparison is now described. The algorithm supports in-memory searching for minimum and maximum of bulk data stored in dynamic random-access memory (DRAM) as unsigned & signed integers, fixed-point and floating numbers. Although the disclosed algorithm and systems make use of XNOR logic, any other equivalent logic implementation may be used.

Finding the minimum/maximum (Min/Max) number is defined as finding the least or greatest (respectively) number in a given list. To fully leverage parallel bit-wise in-DRAM computing capability due to parallel sensing of multiple bit-lines, a core idea of the disclosed systems and methods is to eliminate traditional software-based sequential comparison operations and replace them with XNOR-based bit-wise parallel comparison for all the data stored in one or more memory arrays. In some embodiments, the algorithm refers to a min/max function within one memory array. In other embodiments, where a dataset is large enough that it must necessarily span multiple memory arrays, a large dataset will be first partitioned into multiple memory arrays to get memory-array level min/max values in parallel, from which an overall min/max may be identified using a similar process. FIG. 2 shows the pseudo code of the proposed bit-wise parallel Min/Max-in memory algorithm. The depicted algorithm leverages the property that each bit in the binary format has different significance, and a parallel in-DRAM-XNOR logic-based comparison operation could gradually exclude smaller (or larger) data from MSB (Most Significant Bit) to LSB (Least Significant Bit). The depicted algorithm has a constant searching time determined by the bit length of the values stored in the memory array(s). The depicted algorithm is compatible with unsigned and signed integers, fixed-point numbers and floating numbers, as discussed in more detail below.

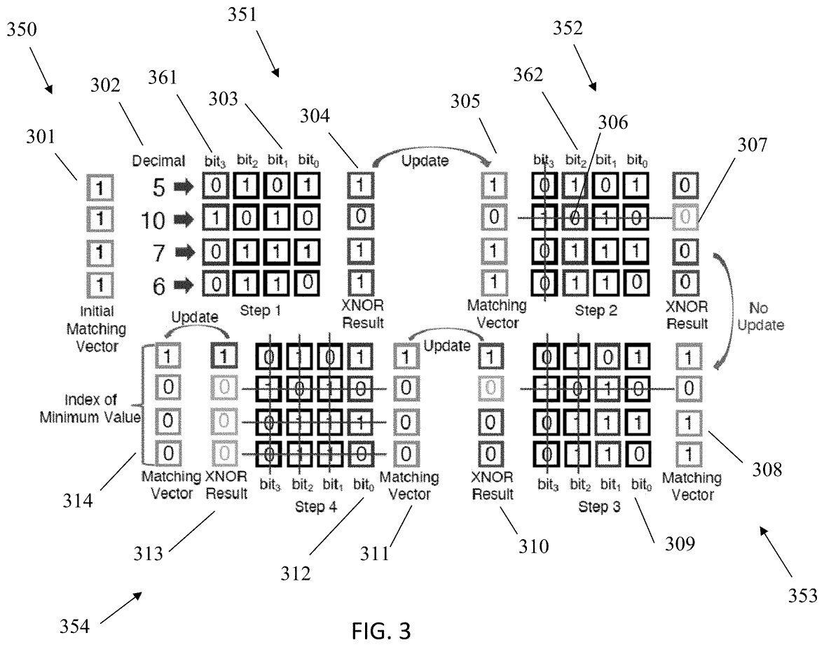

FIG. 3 gives an example graphical representation of an algorithm of the disclosure finding the minimum value in a 4-bit unsigned integer array according to one embodiment of the disclosure. As 4 bits are used to represent unsigned values, 4 iterations are required to compute the index of minimum value(s), in accordance with the constant searching time as mentioned above. In a first step 350, the algorithm initializes a matching vector 301 with all ‘1’s, where the length of vector 301 equals the number of data elements in the array 302. This matching vector will be updated with the outputs of parallel XNOR logic in every iteration except when the parallel XNOR outputs are all ‘0’s (see lines 18 to 22 in FIG. 2). Each element in the matching vector corresponds to one number in the array 303, where ‘1’ indicates this number will be compared in the following iteration, while ‘0’ indicates the corresponding number will be excluded. Starting from the MSB 361, the algorithm applies parallel XNOR logic to the MSB of every number in the array 303 with a constant ‘0’ for the min function (XNOR with a constant ‘1’ for the max function), corresponding to lines 3 to 11 in FIG. 2. Next, the matching vector 301, which began with a value of ‘1111’ is updated with current iteration parallel XNOR output-‘1011’ 304, because the XNOR outputs are not all ‘0’s (see lines 18 to 22 in FIG. 2) to provide the updated matching vector 305.

Continuing the description in step 352, in the second iteration, the new matching vector 305, which has a value-‘1011’ indicates that the second row 306 (marked which in this bit position is a ‘0’) should be excluded from the XNOR comparison operation, will remain as ‘0’ in all following iterations. The step 352 then computes parallel XNOR between the second MSBs 362 of non-excluded numbers and a constant ‘0’ (see line 16 in FIG. 2). In this example, in the second iteration 352, after computing the XNOR between the remaining bits-‘111’ with the constant ‘0’, the outputs are all ‘0’ (see XNOR result 307). Based on FIG. 2 at line-18, the algorithm will skip the step of updating the matching vector after this iteration and the next matching vector 308 will instead be carried over from the previous matching vector 305, continuing into the next iteration 353. Steps 353 and 354 (and additional steps as necessary for longer input values) will continue based on the same rule until the algorithm reaches the LSB 312. Per the example shown in FIG. 3, when the comparison in the LSBs 312 is finished, yielding the final XNOR result 113, the position(s) remaining as ‘1’ in the final matching vector 314 correspond to the index or indices of the minimum value or values in the memory array.

For signed numbers, the basic procedure is the same as the above discussed unsigned numbers except sign bit. In signed numbers, the first bit represents the sign, where ‘1’ and ‘0’ indicate negative and positive, respectively. Therefore, in the appropriate min (or max) function, the algorithm will first check the sign bit. If the sign bits indicate that negative (or positive) values are found, it will exclude all positive (or negative) numbers for the following computation. To do so, as shown in lines 3 to 8 in the algorithm of FIG. 2, a parallel XNOR between sign bits with constant-‘0’ (for max) or ‘1’ (for min) function is needed. Once the sign bit is processed, the remainder of the algorithm will execute identically to the unsigned case.

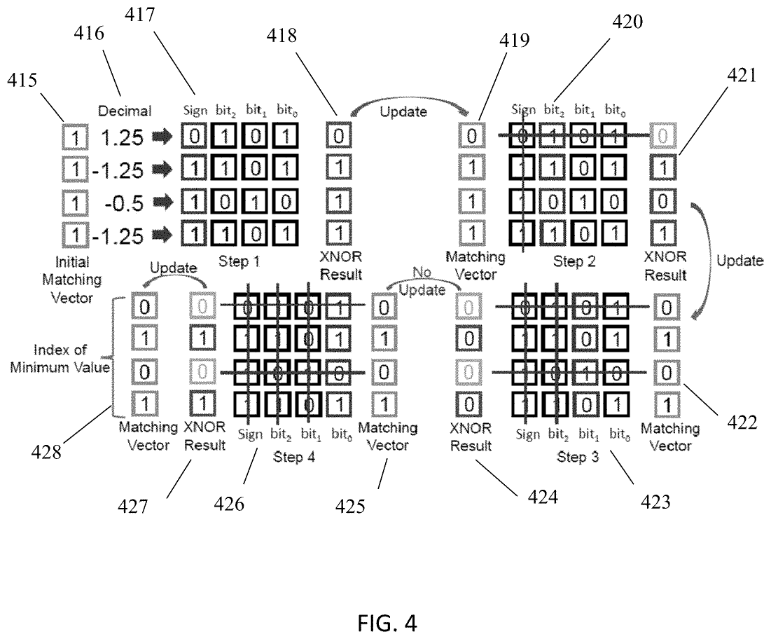

FIG. 4 provides an example to implement a min-in-memory function for a group of four 4-bit signed fixed-point numbers 416. To start, matching vector 415 will be initialized with all ‘1’s. In signed number, the first bit represents the sign, where ‘1’ and ‘0’ indicate negative and positive, respectively. When performing the min function, as detailed above, the algorithm will first check the sign bit 417. In the depicted example, the XNOR result with all 1's first eliminates the top 1.25 from consideration, and the matching vector 418 is updated to reflect this. The remaining three iterations 420, 423, and 426 proceed identically to the unsigned case shown in FIG. 3. The example in FIG. 4 demonstrates that when there are multiple minimum values in the array (i.e. there are multiple identical values stored, all of which have the minimum value), the final matching vector 428 will properly indicate this result with multiple ‘1’s.

The algorithm is also compatible with floating-point numbers. For example, the IEEE754 floating-point number representation is a popular floating-point arithmetic standard. It contains three parts: sign bit, exponent bits, and significand precision. According to the IEEE754, the binary floating-point number may take 16 bits to 256 bits to represent one floating-point number. The bit assignment of the IEEE754 standard dictates that the exponent bits have higher significance than the bits in the fraction part (significand precision). Advantageously, the bits within the exponent part and significand precision obey the same rules as unsigned integer numbers, where bit significance decreases along bit position. Thanks to this bit organization wherein the exponent is on the left side of the fraction part in the endianness (little-endian) sequencing, the proposed Min/Max searching function can be directly applied to floating-point numbers without modification

### In-DRAM Computing Circuit and Architecture

It can be summarized that several important functions are required to be implemented efficiently for in-DRAM computing platform to fully support above algorithm: 1) transpose data copy; 2) fast and parallel in-DRAM XNOR logic; 3) matching vector update; 4) identified min/max index decode.

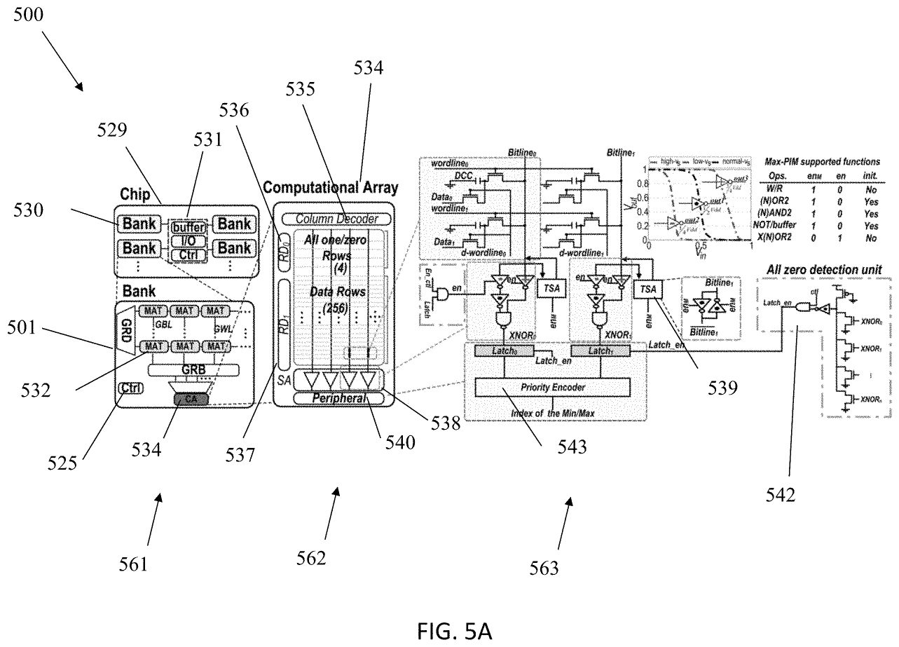

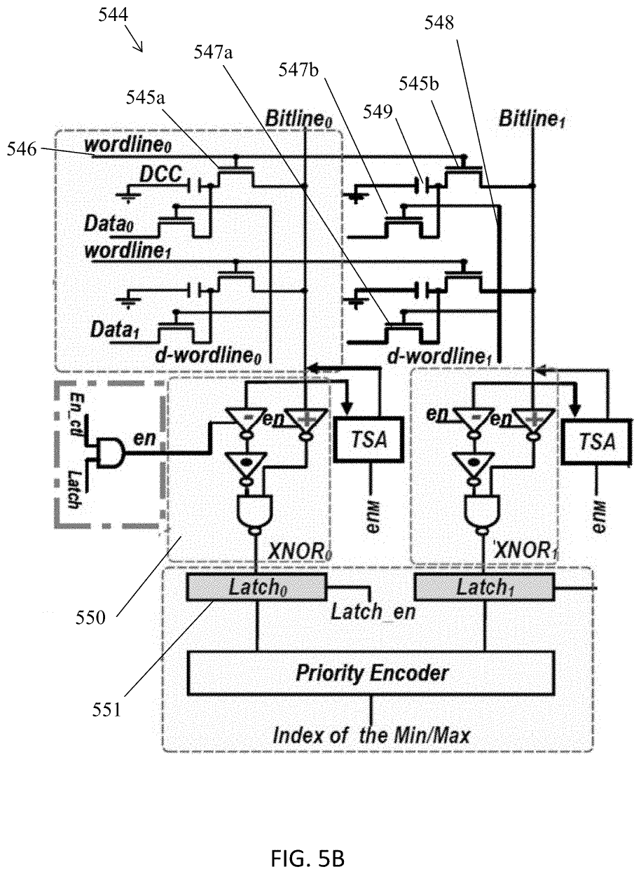

The overall architecture diagram of the proposed Max-PIM is given in FIG. 5A. It keeps the original memory hierarchy by dividing every DRAM chip 529 into multiple banks 530 that share I/O and buffers 531. Each bank 530 contains multiple normal memory matrices (MATs) 532 consisting of typical DRAM subarrays and a single computational array 534. The computational array 535 is developed similar as Ambit, with all Ambit supported logic and instructions, but enhanced to support a new Dual Row Activation (DRA) mechanism to perform XNOR operations in addition to the typical Triple Row Activation (TRA). Each computational array 534 includes: two row decoders 536, 537 (one for data rows and one for all 1/0 rows), one column decoder 535 (to enable transpose copy), modified logic sense-amplifier 538 (to support XNOR logic) with Typical Sense Amplifier 540 (TSA, for memory sensing and charge sharing based majority gate), one latch per bit-line 541 (to store the matching vector and control the logic-SA), pseudo-OR gate 542 (to detect all-zero XNOR outputs), and one priority encoder 543 (to return final index of identified min/max locations).

Element 561 of FIG. 5 depicts the architecture diagram of the proposed hardware design with the DRAM Chip 529 with multiple banks 530 that share I/O and buffers 531. Each bank 530 contains multiple normal memory matrices (MATs) 532 comprising typical DRAM subarrays and a single computational array 534.

Element 562 of FIG. 5A depicts the a detail view of the computational sub-array 534 with components. Each computational array includes two row decoders 536, 537 (one for data rows and one for all 1/0 rows), one column decoder 535 (to enable transpose copy), a modified logic sense-amplifier 538 (to support XNOR logic) with Typical Sense Amplifier 540 (TSA, for memory sensing and charge sharing based majority gate), one latch per bit-line 541 (to store the matching vector and control the logic-SA), a pseudo-OR gate 542 (to detect all-zero XNOR outputs), and a priority encoder 543 (to return the final index or indices of identified min/max locations)

Element 563 of FIG. 5A (shown in detail view in FIG. 5B) depicts the proposed dual-row activation based XNOR logic and peripheral circuits for other operations. Shown is the dual-contact cell (DCC) design 144. In DCC, one transistor (for example 545a) shares its gate with other transistors (for example 545b) on the same row to form the normal row-wise word-line 546. Another transistor 547a shares its gate with other transistors 547b on the same column to form the column-wise write word-line 548, which is controlled by the column decoder 535. The drain and source of the second transistor connect to the cell capacitor 549 and the other normal DRAM array, respectively the Data port.

### Transpose Copy

Due to DRAM's destructive read property, any in-DRAM computing needs to make a copy of operand data to perform in-DRAM-logic. More importantly, based on the proposed min/max-in-memory algorithm, one important operation of each iteration is that parallel XNOR logic must be implemented between the bits in the same bit position of all numbers in the array with a vector of all ‘1’/‘0’, which brings two requirements for in-DRAM computing hardware: 1) for single XNOR logic, both operands (i.e. one specific bit from one number and one constant-‘1’/‘0’) need to be stored in the same bit-line based on the circuit design of in-DRAM-logic that will be explained below, and 2) to fully leverage the parallelism of in-DRAM computing, multiple logic-SAs could be simultaneously activated, which is determined by the size of the memory array. Therefore in the computational memory array, the binary data of a number needs to be stored along the bit-line direction, not along the traditional word-line direction. This in turn requires a transpose copy from data memory to computational memory.

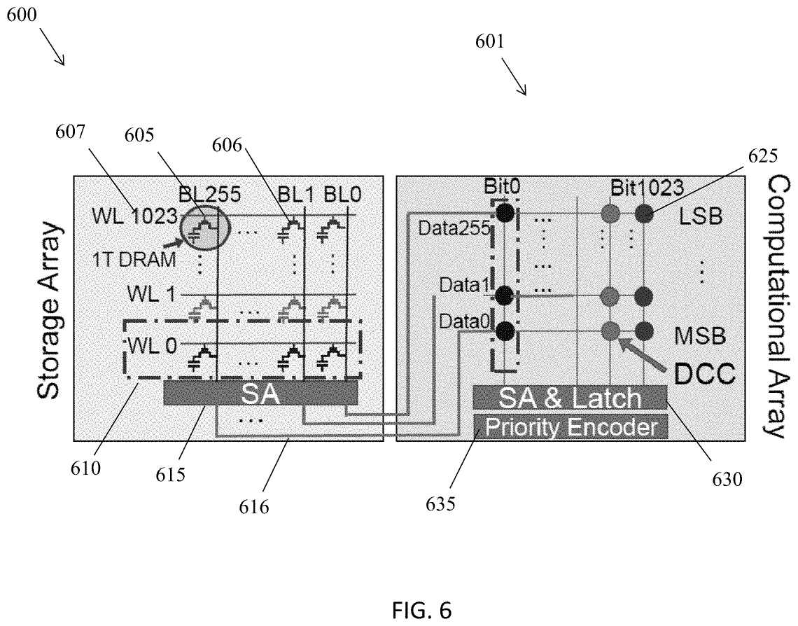

To support the transpose copy operation, adopted is a dual-contact cell (DCC) design shown in FIG. 5A and FIG. 5B, similar to Seshadri (V. Seshadri et al., 2017, MICRO, 2017, pp. 273-287). With reference to FIG. 6, within a DCC, one transistor 605 shares the gate with other transistors 606 on the same row to form the normal row-wise word-line 607. Another transistor (not shown in this diagram) shares the gate with other transistors on the same column to form the column-wise write word-line, which is controlled by the column decoder 535. The drain and source of the second transistor connect to the cell capacitor and the other normal DRAM array, respectively (the Data port 616 Copying operand data from data storage array 600 to computational array 601 requires two steps: (1) reading the entire word-line (e.g. 607) from the data storage array and (2) writing the data to one bit-line (column, e.g. 625) of the computational array with the help of DCC and the column decoder.

### Parallel XNOR Logic in One Cycle

Max-PIM supports all traditional charge sharing based majority gate logic and optimize heavily used XNOR logic with only one cycle. In the proposed min/max-in-memory algorithm, since one operand of XNOR comes from one bit in a specific location of one number in the array, and the other one is constant-‘1’ or ‘0’ for max or min functions, respectively, the operation reserves several rows in the computational array for storing such constant bits. Traditionally, due to the destructive read in DRAM, the operation waits for data refresh of all one/zero rows after every computation. As a result of the DCC cell design that separates the write and read, the operation only uses 2 rows for all ‘1’s and 2 rows for all ‘0’s without introducing extra refresh time by refreshing one row while using the other row for XNOR logic. For the all ‘1/0’ rows, the operation connects the data port of the DCC cells to VDD/GND.

The disclosed in-DRAM XNOR logic circuit is based on the popular Dual-Row Activation scheme (S. Angizi et al., 2019, IEEE/ACM International Conference on Computer-Aided Design (ICCAD), 2019 Issue). First, the bit-lines are pre-charged to VDD2. Then, two word-lines storing the operand data are activated simultaneously, leading to charge sharing between the two cells in the same bitline. This in turn generates different sensing voltages at the associated logic-sense-amplifier (logic-SA) circuit depending on the different values stored in these two cells. This sensed voltage is then compared with different reference voltages to implement different logic functions. In this work, presented is a logic-SA circuit design that could implement XNOR logic in only one cycle as shown in FIG. 5B, where typically multiple cycles are required in most prior works (V. Seshadri et al., 2017, MICRO, 2017, pp. 273-287; R. V. Lebo, 1982, Pattern recognition, vol 3, pp. 145-154). In the circuit, 550, the plus sign marked inverter has a higher threshold voltage, and the minus sign marked inverter has a lower threshold voltage when compared to a normal inverter. It is designed as such so that for the high threshold inverter, the output goes to zero only when both activated cells have high voltage (storing ‘11’) by implementing a NAND function. The low threshold inverter works on the opposite situation that only generates a high output when both cells have low voltage (storing ‘00’) by implementing a NOR function. Therefore, based on XNOR=NAND(OR, NAND), XNOR logic is implemented by adding an inverter and NAND logic circuit following the two skewed inverters as shown in FIG. 5B.

As described by the algorithm in FIG. 2, the matching vector needs to be updated in every searching iteration, except all-zero XNOR outputs. To avoid writing back the XNOR outputs to memory for matching vector update, latches 551 are incorporated in the logic-SA circuits as shown in FIG. 5B to store and update matching vectors. Moreover, to exclude updating in case of all-zero XNOR outputs, an all zero detection unit circuit 542 is designed based on a pseudo OR gate to control the matching vector latch update.

When the iterative XNOR comparison is finished, the final matching vector indicates the indices/location(s) of found min/max values. The disclosed system is therefore able to return the identified min/max data address(es) to user through a priority encoder.

### EXPERIMENTAL EXAMPLES

The invention is further described in detail by reference to the following experimental examples. These examples are provided for purposes of illustration only, and are not intended to be limiting unless otherwise specified. Thus, the invention should in no way be construed as being limited to the following examples, but rather, should be construed to encompass any and all variations which become evident as a result of the teaching provided herein.

Without further description, it is believed that one of ordinary skill in the art can, using the preceding description and the following illustrative examples, make and utilize the system and method of the present invention. The following working examples therefore, specifically point out the exemplary embodiments of the present invention, and are not to be construed as limiting in any way the remainder of the disclosure.

### Experiment 1—Comparing with Other In-DRAM Computing Platforms

Within the experiments, each bank has 16 MATs and each MAT consists of 2 sub-arrays with a size of 1024×256. Each bank contains one computational array shared by all the sub-arrays within the same bank. The computational array size is 260×1024, where 256 rows are used to store data and 4 reserved rows store constant ‘0/1’. Thus, one bank stores ˜1 MB data. Considering 1 GB DRAM capacity, there are 1024 banks for the whole DRAM. For comparison, Ambit and DRISA platforms were constructed with the same organization as Max-PIM, but with their own in-DRAM logic circuits. To enable a fair comparison, all designs used DCC cells for entire computational array to support transpose write.

Max-PIM was compared with two state-of-the-art in-DRAM computing platforms: Ambit and DRISA. To conduct a fair comparison in min/max searching, those designs were implemented with all required peripherals, including a DCC array, column decoder, multiple row decoder, pseudo OR gate, latch (Matching vector), and priority encoder.

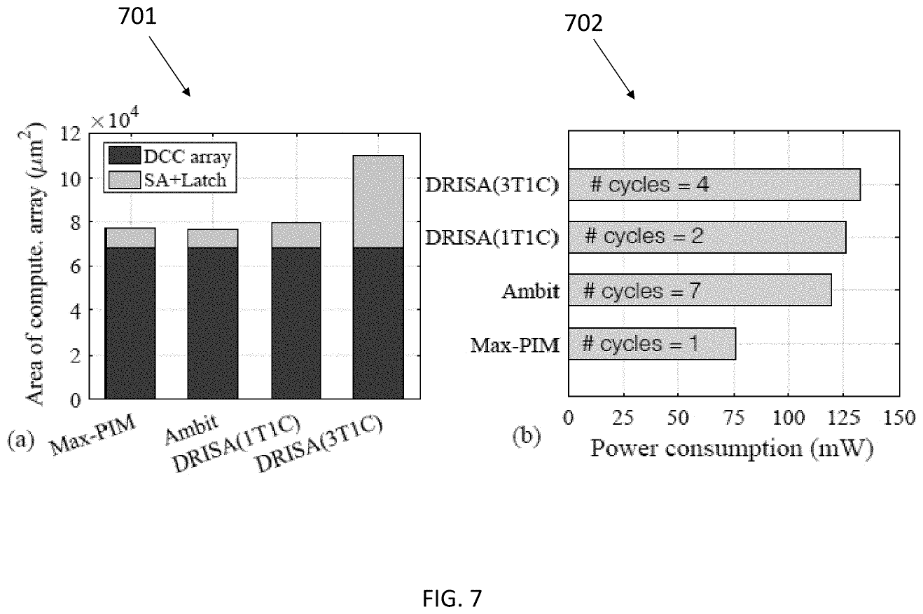

Graph 701 in FIG. 7 depicts the area overhead (μm²) for a single computational array. Displayed are the areas for Max-PIM, Ambit, DRISA (1T1C), and DRISA (3T1C). The plot displays the area of compute for the DCC array as well as the SA+Latch. All the peripheral circuits required to support min/max in-memory algorithm are the same in all implementations. The area difference comes from different logic-SA circuit designs. Graph 701 shows that the disclosed system (Max-PIM) has a similar area overhead as the Ambit and DRISA (1T1C) designs, but DRISA (3T1C) design has a much larger area overhead.

Graph 702 in FIG. 7 shows a comparison of power consumption and clock cycles required for XNOR logic. The figure depicts the power consumption (mW) for Max-PIM, Ambit, DRISA (1T1C), DRISA (3T1C). The number of cycles is shown per each category representing the number of cycles required for the given power consumption. The DRISA (1T1C) uses an XNOR gate at the bottom of every bit-line instead of leveraging the DRA to perform the XNOR, requiring two cycles. Both Ambit and DRISA (3T1C) leverage the multi-row activation to achieve the logic operations, such as AND, OR, and NOT. Ambit needs up to 7 cycles to perform an XNOR operation. DRISA (3T1C) needs to do NOR four times and stores back the intermediate data. Max-PIM by contrast could implement XNOR logic in only one cycle. It avoids intermediate data write back compared with other designs, and thus greatly reduces power consumption and latency.

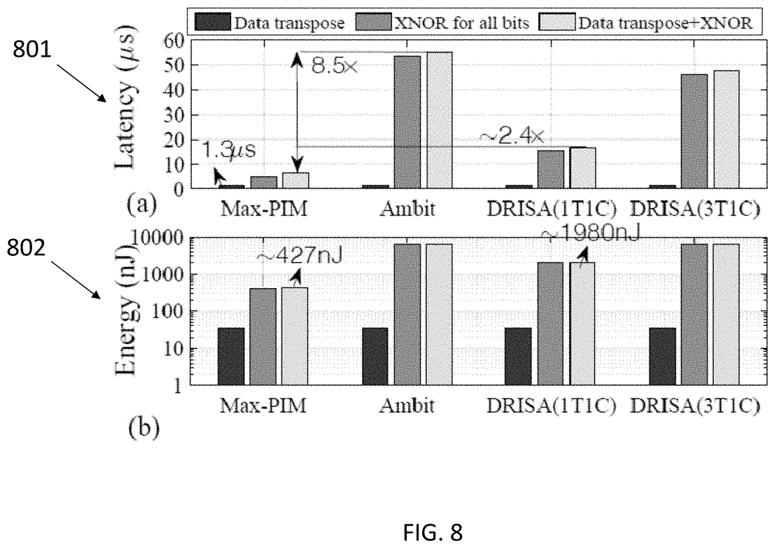

Graph 801 in FIG. 8 summarizes the distribution and comparison of latency Min/Max searching within one computational sub-array. With the DCC and transpose write, data mapping is faster than the computation. Max-PIM is much faster than its counterparts in computing, due at least in part to single-cycle XNOR design.

Graph 802 in FIG. 8 summarizes the distribution and comparison of energy consumption for Min/Max searching within one computational sub-array. Max-PIM shows superior energy efficiency as well in min/max searching.

### Min/Max Searching in Real World Dataset

To evaluate performance, a crosslayer evaluation framework was constructed, starting with a circuit-level evaluation with TSMC 65 nm technology. The same process node was used to re-implement all counterpart designs. The memory peripherals were simulated using the same technology library in Synopsys Design Compiler. The circuit simulation results were then fed into architecture-level tools. An extensive modification of CACTI7.0 was required to extract the performance results. An in-house mapping algorithm was then developed on top of the architecture level to parse the input vector coming from various data-sets and evaluate the performance.

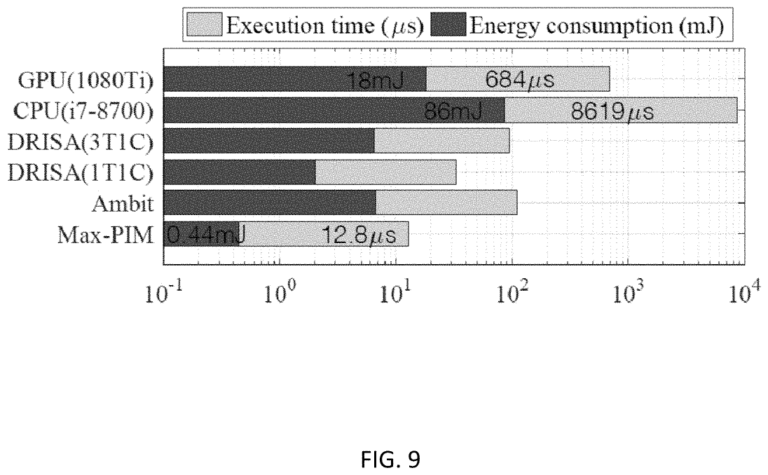

To evaluate the performance of the Max-PIM platform in min/max searching in a real-world dataset, a popular data-set T10I4D100K was used containing 1010228 numbers, where each number is represented as a 256-bit unsigned integer number stored in DRAM. The execution time and energy consumption measurement is shown in FIG. 9 for different computing platforms including Ambit, DRISA, CPU and GPU. For all in-DRAM computing platforms, including the Max-PIM, Ambit and DRISA, such a large array cannot fit into a single computational array, thereby necessarily requiring data partitioning. The total 1010228 numbers were partitioned into 987 computational sub-arrays, where each sub-array computed in parallel to return a local minimal number. Then, the local minimal numbers were written into another computational array to get the global minimum number. For CPU&GPU evaluation, the reported time is total execution time, including data loading from main memory and processing. For energy estimation, similar to DRISA, the CPU&GPU were scaled down to 50% average power to exclude the power cost of cooling, voltage regulators, etc. Among in-DRAM computing platforms, Max-PIM achieves the lowest latency and energy consumption. Max-PIM could achieve a ˜50-˜1000% speed improvement, and energy consumption at least one order of magnitude less than GPU&CPU.

### Applications in Sorting and Graph Processing

Table 1 below depicts the sorting performance of different in-DRAM computing platforms and software implementation in CPU. It can be seen that all in-DRAM computing platforms outperform the software implementation in CPU by three orders of magnitude mainly due to savings of large amounts of off-chip data movement and ultra-parallel processing capability. Aligning with prior experiments in single min/max searching, Max-PIM achieved the best performance compared with other in-DRAM computing platforms due to its optimized XNOR and peripheral circuits.

TABLE 1

| | Name | | | | |
|---|---|---|---|---|---|
| | MAX-PIM | Ambit | DRISA(1T1C) | DRISA(1T1C) | CPU |
| Time(sec) | 6.49 | 55.6 | 16.83 | 47.86 | 9888.05 |

Table 2 below depicts the min/max searching speedup over CPU in Dijkstra's Algorithm. Reported is the Min/Max searching speed improvement over CPU for different in-DRAM computing platforms. A similar performance improvement trend was observed. In general, in-DRAM computing platforms could all achieve one to two orders of magnitude speed up over CPU, and Max-PIM still outperforms all other in-DRAM computing platforms significantly. Meanwhile, it was also observed that a larger speed up is achieved for a larger dataset, clearly proving again that the memory-wall becomes the bottleneck when dealing with larger datasets.

TABLE 2

| Name | geom(7343) | foldoc(13356) | EAT_SR(23219) |
|---|---|---|---|
| MAX-PIM | 91X | 167.74X | 466.29X |
| Ambit | 9.78X | 18.68X | 18.68X |
| DRISA(1T1C) | 34.62X | 64.03X | 179.07X |
| DRISA(3T1C) | 11.53X | 21.84X | 62.32X |

Dijkstra's algorithm is a popular and widely used algorithm in graph processing used to find the shortest path in large graphs, where min/max searching dominates overall computation. Three different datasets were used here: geom has 7343 nodes, foldoc has 13356 nodes and EAT SR has 23219 nodes. Table 2 above reports the Min/Max searching speed improvement over CPU for different in-DRAM computing platforms.

In this example, the Max-PIM system was utilized in real-word applications of data sorting and Dijkstra's algorithm in graph processing to further evaluate performance. For the sorting evaluation, the dataset was the same as the one used in the previous experiment. Leveraging the parallel min/max searching provided by Max-PIM, the min/max sorting algorithm was used, where each round finds the min or max to iteratively sort the data. The performance of different in-DRAM computing platforms and software implementations in CPU is reported in Table 1. It can be seen that all in-DRAM computing platforms outperform the software implementation in CPU by three orders of magnitude mainly due to the prevention of large amounts of off-chip data movement and ultra-parallel processing capability. Aligning with prior experiments in single min/max searching, Max-PIM achieved the best performance compared with other in-DRAM computing platforms due to its optimized XNOR and peripheral circuits.

### REFERENCES

The following publications are incorporated herein by reference in their entireties.
V. Seshadri et al., “Ambit: In-memory accelerator for bulk bitwise operations using commodity dram technology,” in 2017 MICRO, 2017, pp. 273-287.
S. Li et al., “Drisa: A dram-based reconfigurable in-situ accelerator,” in 2017 MICRO, 2017, pp. 288-301.
R. V. Lebo, “Chromosome sorting and dna sequence localization,” Cytometry: The Journal of the International Society for Analytical Cytology, vol. 3, pp. 145-154, 1982.
M. A. Ismail et al., “Multidimensional data clustering utilizing hybrid search strategies,” Pattern recognition, vol. 22, pp. 75-89, 1989.
L. Page et al., “The pagerank citation ranking: Bringing order to the web.” Stanford InfoLab, Tech. Rep., 1999.
A. Boroumand et al., “Google workloads for consumer devices: Mitigating data movement bottlenecks,” SIGPLAN Not., vol. 53, no. 2, p. 316-331, March 2018.
S. Angizi et al., “Redram: A reconfigurable processing-in-dram platform for accelerating bulk bit-wise operations,” in 2019 IEEE/ACM International Conference on Computer-Aided Design (ICCAD), 2019.
Q. Deng et al., “Dracc: a dram based accelerator for accurate cnn inference,” in 2018 DAC, 2018, pp. 1-6.
V. Seshadri et al., “Rowclone: fast and energy-efficient in-dram bulk data copy and initialization,” in Micro, 2013, pp. 185-197.
P.-E. Danielsson, “Getting the median faster,” Computer Graphics and Image Processing, vol. 17, no. 1, pp. 71-78, 1981.
M. Vacca et al., “Logic-in-memory architecture for min/max search,” in 2018 ICECS, 2018, pp. 853-856.
S. Angizi and D. Fan, “Accelerating bulk bit-wise X(N)OR operation in processing-in dram platform,” CoRR, vol. abs/1904.05782, 2019.
R. Balasubramonian et al., “Cacti 7: New tools for interconnect exploration in innovative off-chip memories,” ACM Trans. Archit. Code Optim., vol. 14, no. 2, June 2017.
D. B. Johnson, “A note on dijkstra's shortest path algorithm,” J. ACM, vol. 20, no. 3, p. 385-388, July 1973.
T. A. Davis and Y. Hu, “The university of Florida sparse matrix collection,” ACM Trans. Math. Softw., vol. 38, no. 1, December 2011.

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations.

What is claimed is:

1. A method of calculating a boundary value selected from a minimum or a maximum value of a set of N numerical values in a volatile memory, comprising:
storing a set of N numerical values, each being represented by at least K bits, in a volatile memory;
initializing a comparison vector of at least N bits with all 1s or all 0s;
initializing a matching vector of N bits with all 1s;
transpose-copying a first bit of each of the set of N numerical values into an N-bit buffer;
a) calculating a bitwise XNOR of the comparison vector with the N-bit buffer to obtain an N-bit result vector;
b) determining whether the N-bit result vector contains all zeros;
c) if the N-bit result vector does not contain all zeroes, updating the matching vector to set a 0 at each bit position corresponding to a 0 in the N-bit result vector;
repeating the steps a, b, and c K times for each of the K bits in the set of N numerical values; and
returning the matching vector, where the position of each 1 remaining in the matching vector corresponds to an index of the boundary value in the set of N numerical values;
wherein the computation and the memory storage take place on the same integrated circuit.

2. The method of claim 1, wherein the boundary value is a minimum and the comparison vector is initialized with all 0s.

3. The method of claim 1, wherein the boundary value is a maximum and the comparison vector is initialized with all 1s.

4. The method of claim 1, wherein the bitwise XNOR is performed in a single clock cycle.

5. The method of claim 1, wherein the step of initializing the comparison vector includes initializing two first comparison vectors of all 1s and initializing two second comparison vectors of all 0s.

6. The method of claim 5, wherein, further comprising refreshing one of the two first comparison vectors while the other of the two first comparison vectors is being used to calculate the result vector; or
refreshing one of the two second comparison vectors while the other of the two second comparison vectors is being used to calculate the result vector.

7. The method of claim 1, further comprising storing the result vector in an N-bit latch.

8. The method of claim 7, further comprising disabling the latch if the N-bit result vector contains all zeros.

9. A system for in-memory boundary value calculation, comprising:
a volatile computer-readable memory storing a set of binary values;
a computational array communicatively connected to the volatile computer-readable memory, comprising:
a buffer;
a transposing circuit configured to read data from the volatile computer-readable memory and store a transposed copy of the data into a buffer of the computational array; and
a set of combinatorial logic gates configured to return a bitwise result vector from two input vectors stored in the buffer; and
a processor configured to calculate a matching vector by iteratively removing any bit positions flagged by the result vector from the matching vector as the combinatorial logic gates iterate along the binary values in the set from a most significant bit to a least significant bit.

10. The system of claim 9, further comprising an all-zero detection unit configured to detect when the result vector contains all zeros.

11. The system of claim 10, wherein the computational array is configured to not update the matching vector when the all-zero detection unit detects the result vector containing all zeros.

12. The system of claim 9, wherein the computational array further comprises at least one vector of constant values stored in the buffer whose value stays constant during the matching vector calculations.

13. The system of claim 9, wherein the computational array further comprises a priority encoder configured to update the matching vector with each iteration of the combinatorial logic gates.

14. The system of claim 9, wherein the set of combinatorial logic gates comprises first and second inverters configured with different threshold voltages.

15. The system of claim 9, wherein the combinatorial logic gates are configured to perform a bitwise XNOR operation on the two input vectors.

16. The system of claim 9, wherein the computational array and the volatile computer-readable memory are positioned on a single printed circuit board.

17. The system of claim 16, wherein the processor is positioned on the single printed circuit board.

18. The system of claim 16, wherein the computational array and the volatile computer-readable memory are positioned in a single integrated circuit.

19. The system of claim 18, wherein the processor is positioned in the single integrated circuit.

20. The system of claim 9, wherein the processor is further configured to detect whether the set of binary values are signed, and to change the behavior of the combinatorial logic for a most significant bit of the signed binary values.
